(19) United States
(12) Patent Application Publication
(10) Pub. No.: US 2026/0303081 A1
(43) Pub. Date: Oct. 1, 2026

(54) GATE DRIVER CIRCUITS AND BRIDGE DRIVER CIRCUITS FOR POWER SWITCHES

(71) Applicant: Monolithic Power Systems, Inc.., Kirkland, WA (US)

(72) Inventors: Chao-Chang Chiu, Zhubei City (TW); Yang-Sheng Lin, New Taipei City (TW); Yu-Huei Lee, New Taipei City (TW)

(21) Appl. No.: 19/097,733

(22) Filed: Apr. 1, 2025

(51) Int. Cl. H03K 17/0812; H02M 1/08

(52) U.S. Cl. CPC H03K 17/08122; H02M 1/08

(57) ABSTRACT

A gate driver circuit has a first output switch circuit coupled between a first supply voltage node supplied by a first supply voltage and a first output terminal, a second output switch circuit coupled between a second output terminal and a second supply voltage node supplied by a second supply voltage, and an open detection circuit connected to the first output terminal. The first and second output terminals are adapted to be coupled to a control terminal of a power switch to provide a switch driving signal for controlling ON/OFF switching of the power switch. The open detection circuit and the first output terminal detect an open connection on the first or second output terminal connected to the control terminal of the power switch, before the ON/OFF switching of the power switch.

### TECHNICAL FIELD

This disclosure relates generally to electronic circuits, and more particularly but not exclusively relates to gate driver circuits and bridge driver circuits for power switching devices.

### BACKGROUND

In power converter applications, gate driver circuits are generally used to drive power switches, such as power metal-oxide semiconductor field effect transistor (MOSFET), insulated gate bipolar transistor (IGBT), etc. Bridge driver circuits are popular in a half-bridge circuit of power conversion or power management applications for handling high power or high voltage. Most widely used gate driver circuits come in a compact and low-cost package, but those drivers cannot provide monitoring for package faults (open output pins or missing bonding wires).

### SUMMARY

There has been provided, in accordance with an embodiment of the present disclosure, a gate driver circuit has a first supply voltage node configured to receive a first supply voltage, a second supply voltage node configured to receive a second supply voltage lower than the first supply voltage, a first output switch circuit coupled between the first supply voltage node and a first output terminal of the gate driver circuit, a second output switch circuit coupled between a second output terminal of the gate driver circuit and the second supply voltage node, and an open detection circuit connected to the first output terminal. The first and second output terminals are adapted to be coupled to a control terminal of a power switch to provide a switch driving signal for controlling ON/OFF switching of the power switch. The open detection circuit and the first output terminal are configured to detect an open connection on the first or second output terminal connected to the control terminal of the power switch, before the ON/OFF switching of the power switch.

There has also been provided, in accordance with an embodiment of the present disclosure, a gate driver circuit has a first terminal to receive a pulse width modulated signal having a set logic state and a reset logic state, a second terminal configured to receive a first supply voltage, a third terminal configured to receive a second supply voltage lower than the first supply voltage, a first output switch circuit coupled between the second terminal and a fourth terminal of the gate driver circuit, a second output switch circuit coupled between a fifth terminal of the gate driver circuit and the third terminal, and an open detection circuit connected to the fourth terminal. The fourth and fifth terminals are configured to be coupled to a control terminal of a power switch to provide a switch driving signal for controlling ON/OFF switching of the power switch based on the pulse width modulated signal. The open detection circuit and the fourth terminal are configured to detect an open connection on the fourth or fifth terminal connected to the control terminal of the power switch, before the ON/OFF switching of the power switch.

There has also been provided, in accordance with an embodiment of the present disclosure, a bridge driver circuit has a reference terminal, a first supply voltage node configured to receive by a positive supply voltage relative to a potential of the reference terminal, a second supply voltage node configured to receive a negative supply voltage relative to the potential of the reference terminal, a first output switch circuit coupled between the first supply voltage node and a first output terminal of the bridge driver circuit, a second output switch circuit coupled between a second output terminal of the bridge driver circuit and the second supply voltage node, and an open detection circuit connected to the first output terminal. The first and second output terminals are configured to be coupled to a control terminal of a power switch to provide a switch driving signal for controlling ON/OFF switching of the power switch. The open detection circuit and the first output terminal are configured to detect an open connection on the first or second output terminal connected to the control terminal of the power switch, before the ON/OFF switching of the power switch.

### BRIEF DESCRIPTION OF DRAWINGS

The following detailed description of various embodiments of the present invention can best be understood when read in conjunction with the following drawings, in which the features are not necessarily drawn to scale but rather are drawn as to best illustrate the pertinent features.

FIG. 1 schematically illustrates a gate driver circuit 100 for driving a power switch in accordance with an embodiment of the present disclosure.

FIG. 2 illustrates a block diagram of a gate driver circuit 100a with isolation in accordance with an embodiment of the present disclosure.

FIG. 3 illustrates an exemplary schematic diagram of an open detection circuit 103A used in a gate driver circuit 100b in accordance with an exemplary embodiment of the present disclosure.

FIG. 4 illustrates an exemplary schematic diagram of an open detection circuit 103B used in a gate driver circuit 100c in accordance with an exemplary embodiment of the present disclosure.

FIG. 5 schematically illustrates a bridge driver circuit 200 for driving a half-bridge circuit in accordance with an embodiment of the present disclosure.

FIG. 6 schematically illustrates a flow diagram of a method 700 used in a gate driver circuit in accordance with an embodiment of the present invention.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid unnecessarily obscuring aspects of the present invention. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims.

Reference to “one embodiment”, “an embodiment”, “an example” or “examples” means: certain features, structures, or characteristics are contained in at least one embodiment of the present invention. These “one embodiment”, “an embodiment”, “an example” and “examples” are not necessarily directed to the same embodiment or example, although it may. Furthermore, the features, structures, or characteristics may be combined in one or more embodiments or examples. In addition, it should be noted that the drawings are provided for illustration and are not necessarily to scale. Throughout the specification and claims, the term “coupled,” as used herein, is defined as directly or indirectly connected in an electrical or non-electrical manner. And when an element is described as “connected” or “coupled” to another element, it can be directly connected or coupled to the other element, or there could exist one or more intermediate elements. In contrast, when an element is referred to as “directly connected” or “directly coupled” to another element, there is no intermediate element. The terms “a,” “an,” and “the” include plural reference, and the term “in” includes “in” and “on” unless the context clearly dictates otherwise. The term “or” is an inclusive “or” operator, and is equivalent to the term “and/or” herein including “and”, “or” and any combination thereof, unless the context clearly dictates otherwise. Where either a field effect transistor (“FET”) or a bipolar junction transistor (“BJT”) may be employed as an embodiment of a transistor, the scope of the words “gate”, “drain”, and “source” includes “base”, “collector”, and “emitter”, respectively, and vice versa. Those skilled in the art should understand that the meanings of the terms identified above do not necessarily limit the terms, but merely provide illustrative examples for the terms.

The terms “comprise”, “include”, “have” and any variations thereof, are intended to cover non-exclusive inclusions, such that a process, method, article, or apparatus that comprises a list of elements is not necessarily limited to those elements, may include other elements not expressly listed or inherent to such process, method, article, or apparatus.

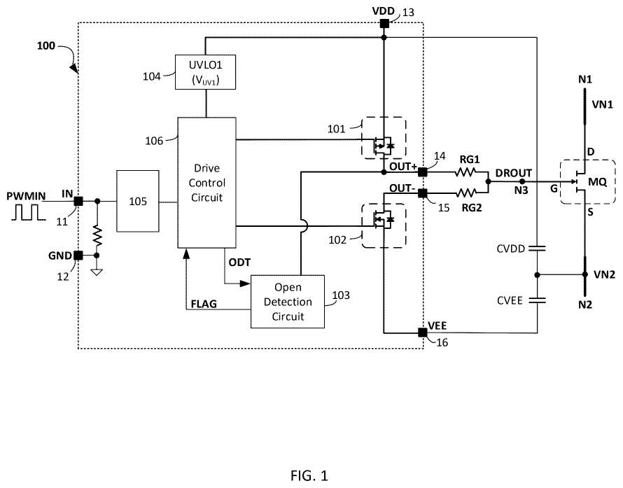

FIG. 1 schematically illustrates a gate driver circuit 100 for driving a power switch in accordance with an embodiment of the present disclosure. The gate driver circuit 100 may be adapted to drive a switching device. The switching device may be any controllable semiconductor device, such as MOSFET (metal oxide semiconductor field effect transistor), IGBT (isolated gate bipolar transistor), SiC (Silicon Carbide), GaN (Gallium Nitride) and so on. For example, when being used in power conversion applications, the gate driver circuit 100 may be configured to drive the switching device to perform ON and OFF switching. In the example shown in FIG. 1, the switching device is illustratively shown as a power switch MQ. However, this is not intended to be limiting.

In accordance with an exemplary embodiment of the present invention, the gate driver circuit 100 may have a first output switch circuit 101, a second output switch circuit 102, an open detection circuit 103 and a plurality of terminals. The plurality of terminals of the gate driver circuit 100 may have a first terminal 11 that may be configured as an input terminal IN, a second terminal 12 that may be configured as a reference ground terminal GND, a third terminal 13 that may be configured as a first supply voltage node VDD, a fourth terminal 14 that may be configured as a first output terminal OUT+, a fifth terminal 15 that may be configured as a second output terminal OUT−, a sixth terminal 16 that may be configured as a second supply voltage node VEE, as shown in FIG. 1.

In the example shown in FIG. 1, the input terminal IN may be adapted to receive a pulse width modulated signal PWMIN. The pulse width modulated signal PWMIN may include a reset logic state (e.g., logic low) and a set logic state (e.g., logic high).

A high potential supply voltage VVDD is provided to the first supply voltage node VDD and is configured to be high enough for turning on the power switch MQ. The high potential supply voltage VVDD is output to the first output terminal OUT+ via the first output switch circuit 101. In the example shown in FIG. 1, the first output switch circuit 101 is interposed or coupled between the first supply voltage node VDD and the first output terminal OUT+. The first output switch circuit 101 is made up of a pMOSFET that is turned on and off by a drive control circuit 106. That is, in FIG. 1, the high potential supply voltage VVDD is applied via the pMOSFET to the first output terminal OUT+ in response to the set logic state of the pulse width modulated signal PWMIN.

Also, a low potential supply voltage VVEE lower than the high potential supply voltage VVDD is provided to the second supply voltage node VEE, and is configured to turn off the power switch MQ. The low potential supply voltage VVEE is output to the second output terminal OUT− via the second output switch circuit 102. In the example shown in FIG. 1, the second output switch circuit 102 is interposed or coupled between the second output terminal OUT− and the second supply voltage node VEE and is made up of an nMOSFET that is also turned on and off by the drive control circuit 106. That is, in FIG. 1, the low potential supply voltage VVEE is applied via the nMOSFET to the second output terminal OUT− in response to the reset logic state of the pulse width modulated signal PWMIN.

As shown in FIG. 1, the first output terminal OUT+ may be adapted to be coupled to a control terminal G of the power switch MQ, e.g., with or without a gating resistive device RG1, while the second output terminal OUT− may be adapted to be coupled to the control terminal G of the power switch MQ, e.g., with or without a gating resistive device RG2. In an example, the gating resistive devices RG1 and RG2 may include parasitic resistances.

Referring still to FIG. 1, a first terminal D of the power switch MQ may be coupled to a power node N1 while a second terminal S of the power switch MQ may be coupled to a power node N2. The power switch MQ may sustain a voltage drop VDS between the first terminal D and the second terminal S. The voltage drop VDS may be indicative of a potential difference (VN1−VN2) between the power node N1 and the power node N2. When the power switch MQ is OFF, an electrical conduction path, for instance a current flowing path, between the power node N1 and the power node N2 is blocked or cut off. Once the power switch MQ is turned ON, the electrical conduction path between the power node N1 and the power node N2 is switched ON to allow current flowing between the power node N1 and the power node N2.

In accordance with an exemplary embodiment of the present invention, when the gate driver circuit 100 is used for practical application configurations, the first output terminal OUT+ may be adapted to be coupled to a common driving connection node N3 for instance with or without the first resistive device RG1. The second output terminal OUT− may be adapted to be coupled to the common driving connection node N3 for instance with or without the second resistive device RG2. The common driving connection node N3 may be coupled to the control terminal G of the power switch MQ. In this way, the first output terminal OUT+ and the second output terminal OUT− are adapted to be coupled to the control terminal G of the power switch MQ to provide a switch driving signal DROUT for controlling ON/OFF switching of the power switch MQ in accordance with the pulse width modulated signal PWMIN, as shown in FIG. 1. The switch driving signal DROUT may include a driving reset logic state that may be adapted to drive the power switch MQ OFF and a driving set logic state that may be adapted to drive the power switch MQ ON.

In accordance with an exemplary embodiment of the present invention, the drive control circuit 106 is coupled between the input terminal IN and the output switch circuits (101 and 102). The drive control circuit 106 may be configured to control the first and second output switch circuits 101 and 102 to generate the switch driving signal DROUT of the power switch MQ.

In an embodiment, the high potential supply voltage VVDD is an internal supply voltage supplied to various circuit blocks, such as the drive control circuit 106 and the first and second output switch circuits 101 and 102 of the gate driver circuit 100. A first capacitive device CVDD may be coupled to the first supply voltage node VDD in practical application. In an exemplary embodiment, the first capacitive device CVDD and a second capacitive device CVEE may be coupled in series between the first supply voltage node VDD and the second supply voltage node VEE, and a common connection of the first capacitive device CVDD and the second capacitive device CVEE may be coupled to the power node N2 of the power switch MQ, as shown in FIG. 1.

In the example shown in FIG. 1, the gate driver circuit 100 further include the open detection circuit 103 connected to the first output terminal OUT+. The open detection circuit 103 and the first output terminal OUT+ may be configured to detect an open connection on any output terminal (the first output terminal OUT+ or the second output terminal OUT−) connected to the control terminal G of the power switch MQ, and be configured to generate a fault signal FLAG. This open detection could be conducted before the ON/OFF switching of the power switch MQ.

In one embodiment, the open detection can be performed when an open detection enable signal ODT is issued after the gate driver circuit 100's startup or initialization stage and before the power switch MQ starts operating.

In the example shown in FIG. 1, the gate driver circuit 100 further include a first under voltage protection circuit UVLO1 (labelled as 104) and a signal processing circuit 105. The first under voltage protection circuit UVLO1 that may be configured to detect whether the high potential supply voltage VVDD is below a first under voltage threshold V_{UV1} before performing the open detection. In an embodiment, if the high potential supply voltage VVDD is below the first under voltage threshold V_{UV1}, the first under voltage protection circuit UVLO1 may control the switch driving signal DROUT to be locked at the driving reset logic state. And the open detection enable signal ODT will also not be issued.

The pulse width modulated signal PWMIN may be signal processed by the signal processing circuit 105, for instance through level shifting. However, in an alternative embodiment, the pulse width modulated signal PWMIN may not need to be signal processed by the signal processing circuit 105 before being transmitted to the drive control circuit 106.

In a further embodiment, the gate driver circuit 100 is configured to enable the open detection circuit 103 during a detection time window. The detection time window has a window width and is enabled after the high potential supply voltage VVDD and the low potential supply voltage VVEE are both built up and the second output switch circuit 102 coupled between the second output terminal OUT− and the second supply voltage node VEE is put into a low impedance state.

As used herein, the term “low-impedance state” refers to a state where the impedance is relatively low, the impedance between the second output terminal OUT− and the second supply node VEE is put into a low impedance state so that the source and drain terminals of the nMOSFET are electrically connected to each other. And the corresponding term “high-impedance state” refers to a state where the impedance is relatively high, for example, the impedance between the second output terminal OUT− and the second supply voltage node VEE is put into a high impedance state so that the source and drain terminals of the nMOSFET are not electrically connected to each other.

In one embodiment, the drive control circuit 106 is configured to provide a logic control signal having a set logic state to the gate of the nMOSFET of the second output switch circuit 102, to allow and put the second output switch circuit 102 to be in the low impedance state. In another embodiment, a controllable interconnect can be used to provide additional connection between the source terminal of the nMOSFET and its drain terminal, to allow the second output switch circuit 102 to be in the low impedance state.

In accordance with an exemplary embodiment of the present invention, the first output switch circuit 101 and the second output switch circuit 102 are arranged in a split push-pull configuration. In practical applications, the gate driver circuit 100 with split output gate configuration gives the benefit of separately controlling the turn-on and turn-off path without a diode, in addition, the turn-on communication speed of the power switch MQ could be reduced by using the split output gate configuration compared to a single output configuration.

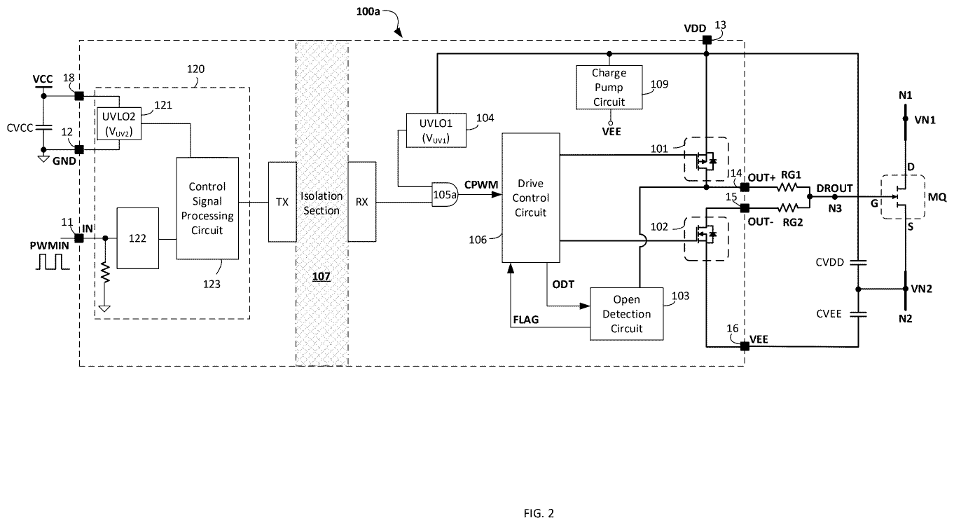

FIG. 2 illustrates a block diagram of a gate driver circuit 100a with isolation in accordance with an embodiment of the present disclosure. Components or structures or elements in the gate driver circuit 100a with substantially the same/similar functions as the gate driver circuit 100 are identified by the same reference labels as used in the gate driver circuit 100 for the sake of simplicity. One of ordinary skill in the art would understand that the gate driver circuit 100a may be considered as an exemplary embodiment of the gate driver circuit 100 further having an isolation section 107 and a primary control circuit 120. Therefore, the above descriptions to the gate driver circuit 100 with reference to FIG. 1 is applicable to the gate driver circuit 100a.

In accordance with an exemplary embodiment, the isolation section 107 may be configured to provide a galvanic isolation between a primary side and a secondary side of the gate driver circuit 100a. The primary control circuit 120 may be disposed at the primary side. The drive control circuit 106 and the first and second output switch circuits 101 and 102 may be disposed at the secondary side.

In the example shown in FIG. 2, the first terminal 11 may be configured as an input terminal IN to receive the pulse width modulated signal PWMIN having a set logic state and a reset logic state. The first terminal 12 may be configured as a primary side reference ground terminal GND for circuitries at the primary side of the gate driver circuit 100a.

The gate driver circuit 100a may further include a terminal 18 that may be configured as a primary side power supply terminal of the gate driver circuit 100a. The terminal 18 may be configured to provide a supply voltage VCC for circuitries at the primary side, such as the primary control circuit 120, etc. A third capacitive device CVCC may be coupled to the terminal 18 in practical application.

In the example shown in FIG. 2, the first supply voltage node VDD may function as a secondary side positive power supply terminal of the gate driver circuit 100a to receive a positive supply voltage VVDD, and the second supply voltage node VEE may function as a secondary side negative power supply terminal of the gate driver circuit 100a to receive a negative supply voltage VVEE at the secondary side of the gate driver circuit 100a. With such configuration, the gate driver circuit 100a may be suitable to be used in power conversion applications that can handle high power or high voltage. One of ordinary skill in the art should understand that this is just to provide an example, the isolation section 107, the circuitries at the primary side (such as the primary control circuit 120) and the associated terminals at the primary side (such as the terminal 18) may be optional or unnecessary for low power or low voltage applications.

The primary control circuit 120 may be configured to transmit the pulse width modulated signal PWMIN to the secondary side for instance through a signal isolation and transmission channel in the isolation section 107 and the signal is transmitted to the secondary side as a pulse width modulated signal CPWM, as shown in FIG. 2. In an embodiment, before being transmitted through the signal isolation and transmission channel, the pulse width modulated signal PWMIN may be signal processed by the primary control circuit 120, for instance as illustrated in the example of FIG. 2. However, in an alternative embodiment, the pulse width modulated signal PWMIN may not need to be signal processed by the primary control circuit 120 before being transmitted through the signal isolation and transmission channel. One of ordinary skill in the art would understand that for embodiments where the isolation section 107 and the circuitries at the primary side are omitted, the pulse width modulated signal PWMIN may be directly provided to, for instance, an input terminal of an AND gate circuit 105a or the drive control circuit 106.

In accordance with an exemplary embodiment, the primary control circuit 120 may include a second under voltage protection circuit UVLO2 (labelled as 121) and may be configured to detect whether the supply voltage VCC is below a second under voltage threshold V_{UV2}. In an embodiment, if the supply voltage VCC is below the second under voltage threshold V_{UV2}, the second under voltage protection circuit UVLO2 may force the switch driving signal DROUT to be locked at the driving reset logic state for instance by an internal active-low clamp circuit which may be included in the drive control circuit 106.

In accordance with an exemplary embodiment, the primary control circuit 120 may further include a filter circuit 122, for instance, for filtering out noise of the pulse width modulated signal PWMIN. In a further embodiment, the primary control circuit 120 may further include a control signal processing circuit 123, for instance, for level shift of the pulse width modulated signal PWMIN.

In the example shown in FIG. 2, the gate driver circuit 100a further include a charge pump circuit 109 that may be coupled between the first supply voltage node VDD and the second supply voltage node VEE and configured to provide the low potential supply voltage VVEE based on the high potential supply voltage VVDD. The charge pump circuit 109 has a capacitor. In one embodiment, the charge pump circuit 109 starts to work after the startup of the first under voltage protection circuit UVLO1.

The drive control circuit 106 is configured to detect whether the high potential supply voltage VVDD is above a first built voltage threshold V1 before initiating an open detection by issuing the open detection enable signal ODT. In an embodiment, if the high potential supply voltage VVDD is below the first built voltage threshold V1, the open detection circuit 103 will be disabled since the high potential supply voltage VVDD has not been built up. In one embodiment, the high potential supply voltage VVDD is built up when the high potential supply voltage VVDD remains 6V, and the first built voltage threshold V1 is, for example, 5.9V.

The drive control circuit 106 is also configured to detect whether the low potential supply voltage VVEE is below a second built voltage threshold V2. In one embodiment, the low potential supply voltage VVEE is built up when the low potential supply voltage VVEE falls down to the second built voltage threshold V2 (e.g., −2.9V).

In accordance with an exemplary embodiment, the drive control circuit 106 may be configured to enable the open detection circuit 103 by issuing the open detection enable signal ODT to initiate the detection time window. The open detection enable signal ODT is issued after the high potential supply voltage VVDD and the low potential supply voltage VVEE are both built up and the second output switch circuit 102 coupled between the second output terminal OUT− and the second supply voltage node VEE is put into the low impedance state.

In a further embodiment, the gate driver circuit 100a is configured to disable the ON/OFF switching of the power switch MQ when the fault signal FLAG is issued. Otherwise, the gate driver circuit 100 is configured to allow the output of the switch driving signal DROUT having a driving set logic state so that the power switch MQ is allowed to be turned on after verifying the absence of the open connection.

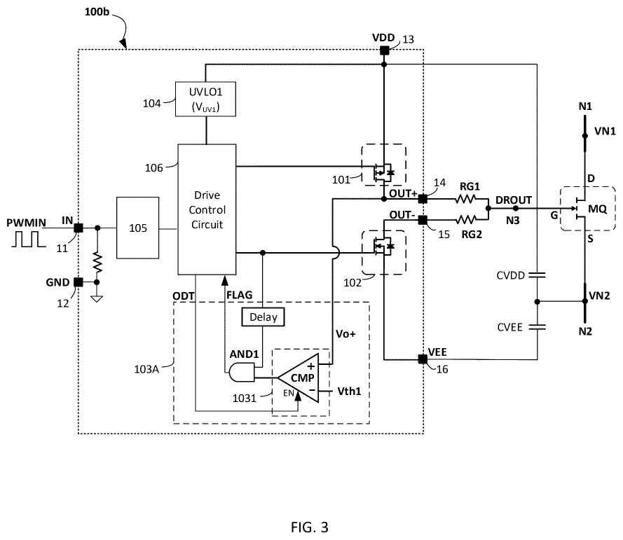

To provide an example, FIG. 3 illustrates an exemplary schematic diagram of an open detection circuit 103A used in a gate driver circuit 100b in accordance with an exemplary embodiment of the present disclosure. Components or structures or elements in the gate driver circuit 100b with substantially the same/similar functions as the gate driver circuit 100 are identified by the same reference labels as used in the gate driver circuit 100 for the sake of simplicity. One of ordinary skill in the art would understand that the gate driver circuit 100b may be considered as an exemplary embodiment of the open detection circuit 103A. In addition, the above descriptions to the gate driver circuits 100~100a with reference to FIG. 1 and FIG. 2 are applicable to the gate driver circuit 100b.

As described above, the open detection circuit 103A is enabled when the high potential supply voltage VVDD and the low potential supply voltage VVEE are both built up, and the second output switch circuit 102 coupled between the second output terminal OUT− and the second supply voltage node VEE is put into the low impedance state. The open detection circuit 103A is configured to detect If there exists an open connection between any output terminal (the first output terminal OUT+ or the second output terminal OUT-) and the control terminal G of the power switch MQ and to generate a fault signal FLAG thereto during the detection time window.

In accordance with an exemplary embodiment, the open detection circuit 103A is configured to compare a voltage VO+ at the first output terminal OUT+ to a first threshold voltage Vth1, and is further configured to indicate an open detection condition by providing the fault signal FLAG with a first logic state (e.g., logic high) in response to the voltage VO+ at the first output terminal OUT+ exceeding the first threshold voltage Vth1 during the detection time window. In an embodiment, the first threshold voltage Vth1 is higher than the low potential supply voltage VVEE. For example, the first threshold voltage Vth1 is −1V, the low potential supply voltage VVEE is −3V.

In the exemplary embodiment shown in FIG. 3, the open detection circuit 103A comprises a comparator CMP, a delay circuit and an AND gate circuit AND1. Before the open detection is performed, the drive control circuit 106 is configured to detect whether the high potential voltage VVDD and the second potential voltage VVEE are both built up, and to provide a logic control signal having a set logic state to turn on the nMOSFET of the second output switch circuit 102 so that the second output switch circuit 102 is put into the low impedance state. After the voltages are built up and the second output switch circuit 102 is put into the low impedance state, the drive control circuit 106 is configured to provide the open detection enable signal ODT to an enable terminal of the comparator CMP for enabling the open detection. The non-inverting input terminal of the comparator CMP is coupled to the first output terminal OUT+ to receive the voltage VO+ at the first output terminal OUT+. The inverting input terminal of the comparator CMP is configured to receive the first threshold voltage Vth1. The delay circuit is configured to provide an internal set delay time. The delay circuit has an input terminal to receive the logic control signal provided by the drive control circuit 106, and an output terminal coupled to a first input terminal of the AND gate circuit AND1. In an example, the logic control signal is also provided to the gate of the nMOSFET of the second output switch circuit 102. An output terminal of the comparator CMP is coupled to a second input terminal of the AND gate circuit AND1. The AND gate circuit AND1 has an output terminal for providing the fault signal FLAG in accordance with the open detection condition.

If there is an open connection between any output terminal(the first output terminal OUT+ or the second output terminal OUT−) and the control terminal G of the power switch MQ, the voltage VO+ at the first output terminal OUT+ will be floating and higher than the low potential supply voltage VVEE (e.g., −3V), for example, higher than the first threshold voltage Vth1 (e.g., −1V). The fault signal FLAG having a first logic state (e.g., logic high) will be issued, and the drive control circuit 106 will disable the operation of the power switch MQ, for example, through locking the switch driving signal DROUT at the driving reset logic state by an internal active-low clamp circuit.

In response to the absence of the open connection, the voltage VO+ at the first output terminal OUT+ substantially equals to the low potential supply voltage VVEE (e.g., −3V). The fault signal FLAG having a second logic state (e.g., logic low) will be provided. As a result, the open detection is passed, the switch driving signal DROUT having a set logic state can be allowed to be provided to the control terminal G of the power switch MQ, so that the power switch MQ is allowed to be turned on, after verifying the absence of the open connection.

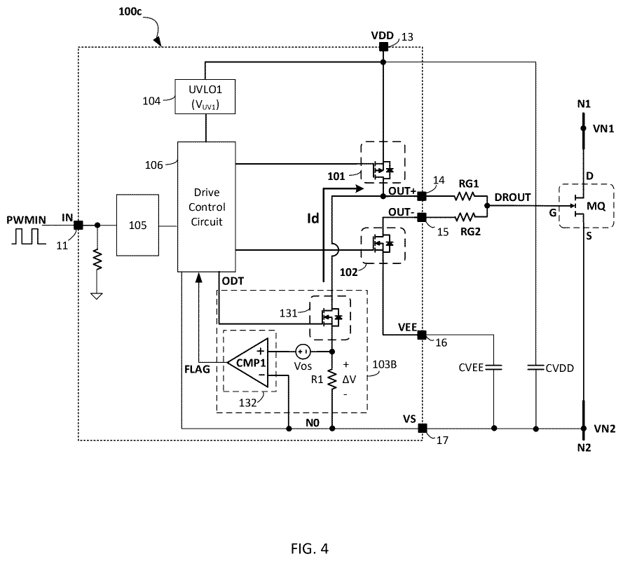

To provide an example, FIG. 4 illustrates an exemplary schematic diagram of an open detection circuit 103B used in a gate driver circuit 100c in accordance with an exemplary embodiment of the present disclosure. Similarly, the above descriptions to the gate driver circuits 100~100b with reference to FIG. 1 to FIG. 3 are also applicable to the gate driver circuit 100c. The open detection circuit 103B is configured to detect whether there exists an open connection between any output terminal (the first output terminal OUT+ or the second output terminal OUT−) and the control terminal G of the power switch MQ during the detection time window.

In accordance with an exemplary embodiment, the open detection circuit 103B is configured to produce a conduction path between the first output terminal OUT+ of the gate driver circuit 100c and a third voltage node NO. The open detection circuit 103B is configured to indicate the open detection condition by providing the fault signal FLAG with the first logic state in response to a positive current Id flowing through the conduction path during the detection time window. In an exemplary embodiment, the potential of the third voltage node NO is set to be higher than the low potential supply voltage VVEE (e.g., −3V) and lower than a turn-on threshold voltage of the power switch MQ to avoid short-through.

Herein, for ease of describing embodiments of the present disclosure, a direction of the current Id “flowing out of” the first output terminal OUT+of the gate driver circuit 100c may be considered as a reference current direction. That is, a current flowing in a direction consistent with the reference current direction may be considered as positive current while a current flowing in a direction opposite to the reference current direction may be considered as negative current.

In the exemplary embodiment shown in FIG. 4, the open detection circuit 103B comprises a comparator CMP1, a third output switch circuit 131, a third resistive device R1 and a bias voltage source Vos. Before the open detection is performed, the drive control circuit 106 is configured to detect whether the high potential supply voltage VVDD and the low potential supply voltage VVEE are both built up, and to provide a logic control signal having a set logic state to turn on the nMOSFET of the second output switch circuit 102 so that the second output switch circuit 102 is put into the low impedance state.

After the high potential supply voltage VVDD and the low potential supply voltage VVEE are both built up and the second output switch circuit 102 is put into the low impedance state, the drive control circuit 106 is configured to provide the open detection enable signal ODT having a set logic state to a control terminal of an nMOSFET of the third output switch circuit 131 for producing the conduction path between the first output terminal OUT+ of the gate driver circuit 100c and the third voltage node NO. If the current Id “flowing in” the first output terminal OUT+ and then into the gate driver circuit 100c, the current Id flowing through the conduction path is considered as negative current, while if the current Id “flowing out of” the first output terminal OUT+ (e.g. then into the gating resistive device RG1), the current Id flowing through the conduction path is considered as positive current.

As shown in FIG. 4, the nMOSFET of the third output switch circuit 131 has a drain terminal coupled to the first output terminal OUT+, a source terminal coupled to the third voltage node NO through the third resistive device R1, and a control terminal configured to receive the open detection enable signal ODT. The comparator CMP1 has a non-inverting input terminal coupled to the source terminal of the nMOSFET of the third output switch circuit 131 via the bias voltage source Vos, an inverting input terminal coupled to the third voltage node NO, and an output terminal for providing the fault signal FLAG to the drive control circuit 106.

In the exemplary embodiment shown in FIG. 4, the gate driver circuit 100c may further include a terminal 17 that may be configured as a power ground terminal VS of the gate driver circuit 100c. For this situation, a potential of the power ground terminal VS is about OV, the high potential supply voltage VVDD relative to a potential of the power ground terminal VS is a positive supply voltage (e.g., 6V), the low potential supply voltage VVEE relative to the potential of the power ground terminal VS is a negative supply voltage (e.g., −3V).

In a further embodiment, the power ground terminal VS may also be configured as a reference ground terminal of the drive control circuit 106.

In an alternative embodiment, the power ground terminal VS can be configured as the third voltage node for open detection, as shown in the example of the open detection circuit 103B.

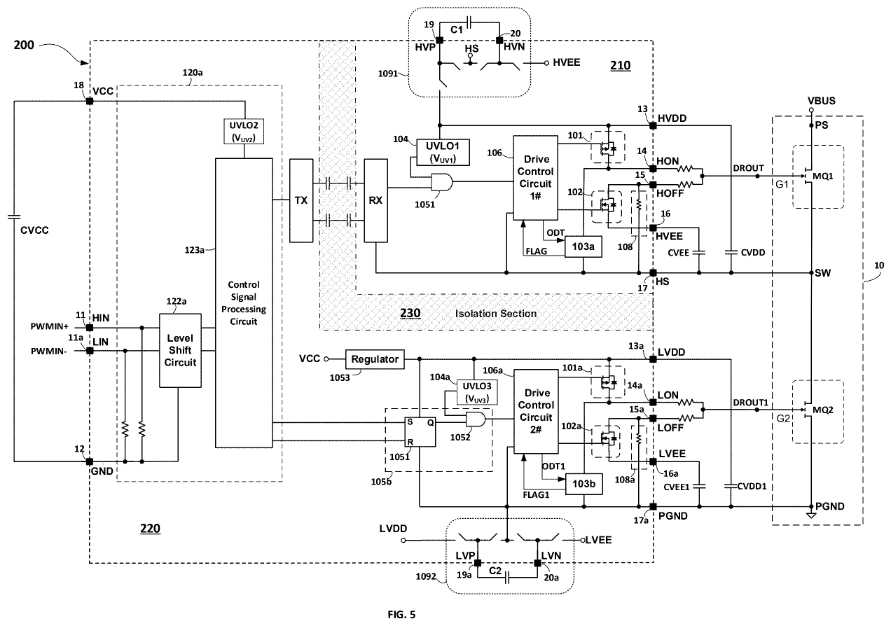

FIG. 5 schematically illustrates a bridge driver circuit 200 for driving a half-bridge circuit in accordance with an embodiment of the present disclosure. As shown in FIG. 5, the bridge driver circuit 200 is configured to control a first power switch MQ1 and a second power switch MQ2 arranged in a half bridge configuration (labelled as a half-bridge circuit 10).

In accordance with an embodiment of the present invention, the half-bridge circuit 10 may include for instance the first power switch MQ1 and the second power switch MQ2 coupled in series between a system power supply terminal PS and a system ground terminal PGND. The first power switch MQ1 and the second power switch MQ2 may have a common node that may be configured as a floating node SW. When the power switches MQ1 and MQ2 are switched in a complementary fashion, voltage variation occurs at the floating node SW. An inductive power storage device may be coupled to the common connection SW. A system supply voltage VBUS may be provided to the system power supply terminal PS. In an example, the system supply voltage VBUS is very high, may be up to 300-600V or above.

In accordance with an exemplary embodiment of the present invention, the bridge driver circuit 200 may have a first gate driving section 210 configured to drive a control terminal G1 of the first power switch MQ1, a second gate driving section 220 configured to drive a control terminal G2 of the second power switch MQ2, and an isolation section 230.

The first gate driving section 210 and the second gate driving section 220 are arranged to be apart from each other. The isolation section 230 may be configured to provide a galvanic isolation between the first gate driving section 210 and the second gate driving section 220 of the bridge driver circuit 200.

In an embodiment, the gate driver circuit 100 and its variants as described with various embodiments of the present disclosure may be employed to implement the first and gate driving sections 210 and 220.

In an alternative example of power conversion apparatus, the first power switch MQ1 may be referred to as another switch which is configured to co-work with the second switch MQ2 without their half-bridge configuration, and vice versa.

In accordance with an exemplary embodiment of the present invention, the bridge driver circuit 200 may have a plurality of terminals including a terminal 11 may that may be configured as a first input terminal HIN, a terminal 11a may that may be configured as a second input terminal LIN, a terminal 12 that may be configured as a reference ground terminal GND, a terminal 13 that may be configured as a first high-side supply voltage node HVDD, a terminal 14 that may be configured as a first high-side output terminal HON, a terminal 15 that may be configured as a second high-side output terminal HOFF, a terminal 16 that may be configured as a second high-side supply voltage node HVEE, a terminal 17 that may be adapted to be a high-side power ground terminal HS, a terminal 13a that may be configured as a first low-side supply voltage node LVDD, a terminal 14a that may be configured as a first low-side output terminal LON, a terminal 15a that may be configured as a second low-side output terminal LOFF, a terminal 16a that may be configured as a second low-side supply voltage node LVEE, a terminal 17a that may be configured as a low-side power ground terminal PGND, and a terminal 18 that may be configured to provide a supply voltage VCC.

In an exemplary embodiment, the terminals 13~17 may be disposed at the first gate driving section 210 of the bridge driver circuit 200 for embodiments having the isolation section 230 that may be suitable to be used in power conversion applications that can handle high power or high voltage. While the terminals 11, 11a, 12, 13a-17a and 18 may be disposed at the second gate driving section 220 of the bridge driver circuit 200 for embodiments having the isolation section 230 that may be suitable to be used in power conversion applications that can handle low power or low voltage.

In the example shown in FIG. 5, the first input terminal HIN may be configured to receive for instance a first pulse width modulated signal PWMIN+, the second input terminal LIN may be configured to receive a second pulse width modulated signal PWMIN−. For this situation, the first pulse width modulated signal PWMIN+ and the second pulse width modulated signal PWMIN− define or determine the pulse width modulated signal PWMIN. In an exemplary embodiment, the first input terminal HIN may be internally pulled at the reset logic state (e.g., logic low) while the second input terminal LIN may be internally pulled at the set logic state (e.g., logic high). The term “internally” here may refer to inside the bridge driver circuit 200. In an embodiment, the bridge driver circuit 200 may be configured to further provide first input and second input overlap protection (also referred to as HIN/LIN overlap protection).

In accordance with an exemplary embodiment of the present invention, the first gate driving section 210 has the first output switch circuit 101 coupled between the first high-side supply voltage node HVDD and the first high-side output terminal HON, the second output switch circuit 102 coupled between the second high-side output terminal HOFF and the second high-side supply voltage node HVEE, and the open detection circuit 103a connected to the first high-side output terminal HON. One of ordinary skill in the art would understand that open detection circuit 103A or 103B discussed before in FIG. 3 and FIG. 4 may be considered as an exemplary embodiment of the open detection circuit 103a or 103b shown in FIG. 5.

The first high-side output terminal HON and the second high-side output terminal HOFF are configured to be coupled to the control terminal G1 of the first power switch MQ1 to provide a first switch driving signal DROUT for controlling ON/OFF switching of the first power switch MQ1. In one example, the first high-side output terminal HON performs a role of turning the first power switch MQ1 ON, and the second high-side output terminal HOFF performs a role of turning the first power switch MQ1 OFF. The open detection circuit 103a and the first high-side output terminal HON are configured to detect an open connection on the second high-side output terminal HOFF (or the first high-side output terminal HON) connected to the control terminal G1 of the first power switch MQ1, and to generate the fault signal FLAG thereto, before the ON/OFF switching of the first power switch MQ1.

In accordance with an exemplary embodiment of the present invention, the high-side power ground terminal HS of the first gate driving section 210 may use the floating node SW between the first power switch MQ1 and the second power switch MQ2, rather than the power ground terminal PGND, as a reference terminal of the circuits.

In accordance with an exemplary embodiment of the present invention, the first gate driving section 210 further include a clamp circuit 108. In an embodiment, the clamp circuit 108 is coupled between the second high-side output terminal HOFF of the bridge driver circuit 200 and the high-side power ground terminal HS of the bridge driver circuit 200 to prevent a voltage at the second high-side output terminal HOFF from exceeding a predetermined level. In an embodiment, the clamp circuit 108 comprises a resistor, as illustrated in the example of FIG. 5.

In accordance with an exemplary embodiment of the present invention, the first gate driving section 210 further include a charge pump circuit 1091. In an embodiment, the charge pump circuit 1091 may be coupled to the first high-side supply voltage node HVDD and the high-side power ground terminal HS, to provide a second high-side power supply voltage for controlling a turning off speed of the first power switch MQ1. For this example, a first external capacitor C1 is used for charge pump function of the charge pump circuit 1091. A first terminal of the first external capacitor C1 is connected to a positive terminal HVP of the bridge driver circuit 200. A second terminal of the first external capacitor C1 is connected to a negative terminal HVN of the bridge driver circuit 200, as illustrated in the example of FIG. 5.

For this example, the second gate driving section 220 of the bridge driver circuit 200 may include a primary control circuit 120a which may be considered as a variant from the primary control circuit 120 shown in FIG. 2. In an exemplary embodiment, the primary control circuit 120a may be disposed in the second gate driving section 220 and may include a second under voltage protection circuit UVLO2. The primary control circuit 120a may further include a level shift circuit 122a and a control signal processing circuit 123a.

In an embodiment, the level shift circuit 122a may be configured to convert certain logic signals from low voltage to high voltage. In an embodiment, the control signal processing circuit 123a may set an internal time delay so that the set logic state (e.g., logic high) of the first pulse width modulated signal PWMIN+and the set logic state (e.g., logic high) of the second the pulse width modulated signal PWMIN-do not overlap.

In addition, the control signal processing circuit 123a is further to generate short-pulse signals to control a bistable circuit 1051, for instance an RS flip-flop, to thereby generate a low-side pulse width modulated signal at an output terminal of the bistable circuit 1051, to a drive control circuit 106a.

The second gate driving section 220 may include a regulator 1051, and a AND gate circuit 1052, and a third under voltage protection circuit UVLO3 (labelled as 104a). The regulator 1051 is configured to receive the power supply voltage VCC at terminal 18 and to provide a first low-side supply voltage to a first low-side supply voltage node LVDD. The third under voltage protection circuit UVLO3 may be configured to detect whether the first low-side supply voltage is below a third under voltage threshold V_{UV3} before performing the open detection.

In accordance with an exemplary embodiment of the present invention, the second gate driving section 220 has the first output switch circuit 101a coupled between the first low-side supply voltage node LVDD and the first low-side output terminal LON, the second output switch circuit 102a coupled between the second low-side output terminal LOFF and the second low-side supply voltage node LVEE, and the open detection circuit 103b connected to the first low-side output terminal LON.

The first low-side output terminal LON and the second low-side output terminal LOFF are configured to be coupled to the control terminal G2 of the second power switch MQ2 to provide a second switch driving signal DROUT1 for controlling ON/OFF switching of the second power switch MQ2. In one example, the first low-side output terminal LON performs a role of turning the second power switch MQ2 ON, and the second low-side output terminal LOFF performs a role of turning the second power switch MQ2 OFF. The open detection circuit 103b and the first low-side output terminal LON are configured to detect an open connection, and to generate a fault signal FLAG1 thereto, before the ON/OFF switching of the second power switch MQ2.

In an embodiment, the first switch driving signal DROUT and the second switch driving signal DROUT1 are configured to turn the first power switch MQ1 and the second power switch MQ2 ON and OFF in a complementary fashion.

When there exists an open connection between the second high-side output terminal HOFF and the control terminal G1 of the first power switch MQ1, the first power switch MQ1 could not be turned off. Similarly, when there exists an open connection between the second low-side output terminal LOFF and the control terminal G2 of the second power switch MQ2, the second power switch MQ2 could not be turned off. If any of the first power switch MQ1 and the second power switch MQ2 is not be turned off, the shoot-through problem of the first power switch MQ1 and the second power switch MQ2 will happen.

In accordance with an exemplary embodiment of the present invention, the second gate driving section 220 further include a clamp circuit 108a coupled between the second low-side output terminal LOFF and the low-side power ground terminal PGND to prevent a voltage at the second low-side output terminal LOFF from exceeding a predetermined level.

In accordance with an exemplary embodiment of the present invention, the second gate driving section 220 further include a charge pump circuit 1092. In an embodiment, the charge pump circuit 1092 may be coupled to the first low-side supply voltage node LVDD and the low-side power ground terminal PGND, to provide a second low-side power supply voltage for controlling a turning off speed of the second power switch MQ2. For this example, a second external capacitor C2 is used for charge pump function of the charge pump circuit 1092. A first terminal of the second external capacitor C2 is connected to a positive terminal LVP of the bridge driver circuit 200. A second terminal of the second external capacitor C2 is connected to a negative terminal LVN of the bridge driver circuit 200, as illustrated in the example of FIG. 5.

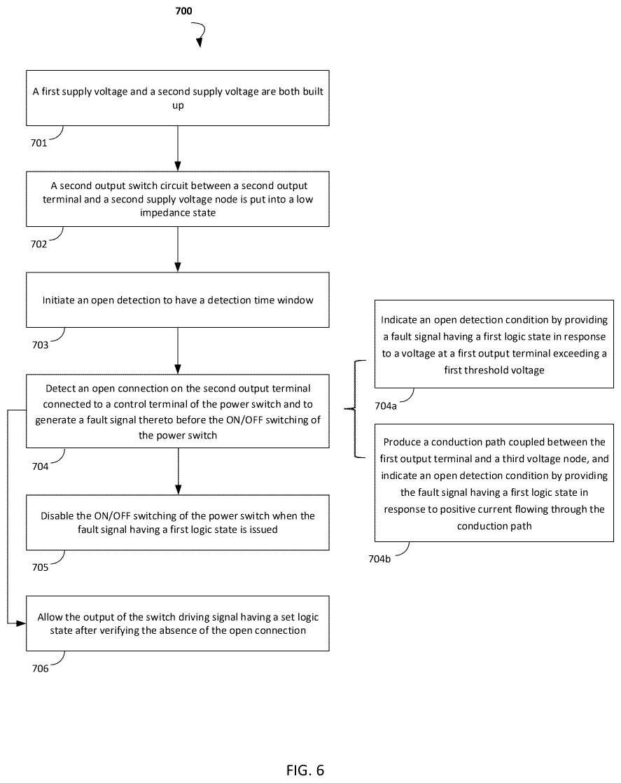

FIG. 6 schematically illustrates a flow diagram of a method 700 used in a gate driver circuit in accordance with an embodiment of the present invention. The method 700 includes the following actions.

In action 701, a first supply voltage and a second supply voltage are built up. The first supply voltage is provided to a first supply voltage node of the gate driver circuit. The second supply voltage is provided to a second supply voltage node of the gate driver circuit. A first output switch circuit of the gate driver circuit is coupled between the first supply voltage node and a first output terminal of the gate driver circuit.

In action 702, a second output switch circuit coupled between a second output terminal of the gate driver circuit and the second supply voltage node of the gate driver circuit is put into a low impedance state.

In action 703, initiating an open detection to have a detection time window.

In action 704, detecting an open connection on the first or second output terminal connected to a control terminal of a power switch, and a fault signal is generated thereto.

In one embodiment, the open connection is detected in response to a voltage at a first output terminal exceeding a first threshold voltage.

In another embodiment, a conduction path between the first output terminal and a third voltage node is produced, and the open connection is detected in response to a positive current flowing through the conduction path.

In action 705, when the open detection fails, the operation of the power switch is disabled.

Alternatively, when the open detection is passed, a switch driving signal having a logic set state can be allowed to be provided to the control terminal of the power switch, to allow the turning-on of the power switch, after verifying the absence of the open connection, as shown in action 706.

The advantages of the various embodiments of the present invention are not confined to those described above. These and other advantages of the various embodiments of the present invention will become more apparent upon reading the whole detailed descriptions and studying the various figures of the drawings.

From the foregoing, it will be appreciated that specific embodiments of the present invention have been described herein for purposes of illustration, but that various modifications may be made without deviating from the technology. Many of the elements of one embodiment may be combined with other embodiments in addition to or in lieu of the elements of the other embodiments. Accordingly, the present invention is not limited except as by the appended claims.

1. A gate driver circuit comprising:
a first supply voltage node configured to receive a first supply voltage;
a second supply voltage node configured to receive a second supply voltage lower than the first supply voltage;
a first output switch circuit coupled between the first supply voltage node and a first output terminal of the gate driver circuit;
a second output switch circuit coupled between a second output terminal of the gate driver circuit and the second supply voltage node, wherein the first and second output terminals are adapted to be coupled to a control terminal of a power switch to provide a switch driving signal; and
an open detection circuit connected to the first output terminal, wherein the open detection circuit and the first output terminal are configured to detect an open connection on the first or second output terminal connected to the control terminal of the power switch, before the ON/OFF switching of the power switch.

2. The gate driver circuit of claim 1, wherein the gate driver circuit is further configured to enable the open detection circuit during a detection time window, and wherein the detection time window is enabled after the first supply voltage and the second supply voltage are both built up and the second output switch circuit is put into a low impedance state.

3. The gate driver circuit of claim 2, wherein the open detection circuit is configured to compare a voltage at the first output terminal to a first threshold voltage, and further to indicate an open detection condition in response to the voltage at the first output terminal exceeding the first threshold voltage during the detection time window.

4. The gate driver circuit of claim 2, wherein the open detection circuit is configured to produce a conduction path between the first output terminal of the gate driver circuit and a third voltage node, and further to indicate an open detection condition in response to a positive current flowing through the conduction path during the detection time window.

5. The gate driver circuit of claim 4, wherein a potential of the third voltage node is higher than the second supply voltage and lower than a turn-on threshold voltage of the power switch.

6. The gate driver circuit of claim 1, further comprising:
an input terminal configured to receive a pulse width modulated signal having a set logic state and a reset logic state;
a drive control circuit configured to control the switch driving signal based on the pulse width modulated signal; and
a reference terminal configured as a reference ground terminal of the drive control circuit.

7. The gate driver circuit of claim 6, further comprising:
a charge pump circuit configured to provide the second power supply voltage to the second supply voltage node based on the first power supply voltage and the potential of the reference terminal.

8. The gate driver circuit of claim 1, wherein:
the gate driver circuit is configured to disable the ON/OFF switching of the power switch when the open connection is detected; and
the gate driver circuit is configured to allow to turn on of the power switch after verifying the absence of the open connection.

9. A gate driver circuit comprising:
a first terminal configured to receive a pulse width modulated signal having a set logic state and a reset logic state;
a second terminal configured to receive a first supply voltage;
a third terminal configured to receive a second supply voltage lower than the first supply voltage;
a first output switch circuit coupled between the second terminal and a fourth terminal of the gate driver circuit;
a second output switch circuit coupled between a fifth terminal of the gate driver circuit and the third terminal, wherein the fourth and fifth terminals are adapted to be coupled to a control terminal of a power switch to provide a switch driving signal for controlling ON/OFF switching of the power switch based on the pulse width modulated signal; and
an open detection circuit connected to the fourth terminal, wherein the open detection circuit and the fourth terminal are configured to detect an open connection on the fourth or fifth terminal connected to the control terminal of the power switch, before the ON/OFF switching of the power switch.

10. The gate driver circuit of claim 9, further comprising:
an isolation section configured to provide a galvanic isolation between a primary side and a secondary side of the gate driver circuit;
a drive control circuit configured to control the switch driving signal based on the pulse width modulated signal; and
a sixth terminal configured as a reference ground terminal of the drive control circuit.

11. The gate driver circuit of claim 10, further comprising:
a seventh terminal disposed at the primary side and configured as a primary side reference ground terminal for circuitries at the primary side of the gate driver circuit; and
an eighth terminal disposed at the primary side and configured as a primary side power supply terminal of the gate driver circuit; and
wherein the fourth terminal, the fifth terminal, the sixth terminal are disposed at the secondary side.

12. The gate driver circuit of claim 10, wherein the drive control circuit is further configured to enable the open detection circuit during a detection time window, and wherein the detection time window is enabled when the first supply voltage and the second supply voltage are both built up and the second output switch circuit is put into a low impedance state.

13. The gate driver circuit of claim 12, wherein the open detection circuit is configured to compare a voltage at the fourth terminal to a first threshold voltage, and further to indicate an open detection condition in response to the voltage at the fourth terminal exceeding the first threshold voltage during the detection time window.

14. The gate driver circuit of claim 12, wherein:
the open detection circuit is configured to produce a conduction path between the fourth terminal and the sixth terminal, and is further configured to indicate an open detection condition in response to a positive current flowing through the conduction path during the detection time window; and
wherein the first supply voltage is a positive supply voltage relative to a potential of the sixth terminal, the second supply voltage is a negative supply voltage relative to the potential of the sixth terminal.

15. The gate driver circuit of claim 10, further comprising:
a clamp circuit coupled between the fifth terminal of the gate driver circuit and the sixth terminal of the gate driver circuit to prevent a voltage at the second output terminal from exceeding a predetermined level.

16. The gate driver circuit of claim 10, wherein:
the drive control circuit is configured to disable the ON/OFF switching of the power switch when the open connection is detected; and
the drive control circuit is configured to allow the turning-on of the power switch after verifying the absence of the open connection.

17. The gate driver circuit of claim 10, further comprising:
a charge pump circuit coupled to the second terminal and the sixth terminal, configured to provide the second power supply voltage for controlling a turning off of the power switch, wherein the second power supply voltage is negative power supply voltage relative to the potential of the sixth terminal.

18. A bridge driver circuit comprising:
a reference terminal;
a first supply voltage node configured to receive a positive supply voltage relative to a potential of the reference terminal
a second supply voltage node configured to receive a negative supply voltage relative to the potential of the reference terminal;
a first output switch circuit coupled between the first supply voltage node and a first output terminal of the bridge driver circuit;
a second output switch circuit coupled between a second output terminal of the bridge driver circuit and the second supply voltage node, wherein the first and second output terminals are adapted to be coupled to a control terminal of a power switch to provide a switch driving signal for controlling ON/OFF switching of the power switch; and
an open detection circuit connected to the first output terminal, wherein the open detection circuit and the first output terminal are configured to detect an open connection on the first or second output terminal connected to the control terminal of the power switch, before the ON/OFF switching of the power switch.

19. The bridge driver circuit of claim 18, wherein:
the reference terminal is configured as a floating node between a high-side power switch and a low-side power switch arranged in a half bridge configuration; and
the power switch is configured as the high-side power switch.

20. The bridge driver circuit of claim 18, wherein:
the reference terminal is configured as a power ground terminal of the bridge driver circuit, wherein a half-bridge circuit comprises a high-side power switch arranged between a power supply node and a floating node as well as a low-side power switch arranged between the floating node and the power ground terminal; and
the power switch is configured as the low-side power switch of the half-bridge circuit.

21. The bridge driver circuit of claim 18, wherein the bridge driver circuit is further configured to enable the open detection circuit during a detection time window, and wherein the detection time window is enabled when the first supply voltage and the second supply voltage are both built up and the second output switch circuit is put into a low impedance state.

22. The bridge driver circuit of claim 21, wherein:
the open detection circuit is configured to compare a voltage at the first output terminal to a first threshold voltage and further to indicate an open detection condition in response to the voltage at the first output terminal exceeding the first threshold voltage during the detection time window.

23. The bridge driver circuit of claim 21, wherein:
the open detection circuit is configured to produce a conduction path between the first output terminal of the bridge driver circuit and a third supply voltage node, and further to indicate an open detection condition in response to a positive current flowing through the conduction path during the detection time window; and
wherein the voltage of the third supply voltage node relative to the potential of the reference terminal is lower than a turn-on threshold voltage of the power switch.

24. The bridge driver circuit of claim 21, wherein:
the open detection circuit is configured to produce a conduction path between the first output terminal of the bridge driver circuit and the reference terminal and further to indicate an open detection condition in response to a positive current flowing through the conduction path during the detection time window.

25. The bridge driver circuit of claim 18, further comprising:
a charge pump circuit coupled to the first supply voltage node and the reference terminal, configured to provide the second power supply voltage for controlling a turning-off of the power switch.
